(19) United States
(12) Patent Application Publication
(10) Pub. No.: US 2023/0307349 A1
(43) Pub. Date: Sep. 28, 2023

(54) SEMICONDUCTOR DEVICE AND METHOD FOR MANUFACTURING THE SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Naoki OKAWA, Ibo Hyogo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 17/942,019

(22) Filed: Sep. 9, 2022

(30) Foreign Application Priority Data
Mar. 22, 2022 (JP) 2022-045393

(51) Int. Cl. H01L 23/498; H01L 23/31; H01L 23/495; H01L 21/48; H01L 21/56; H01L 21/66

(52) U.S. Cl. CPC H01L 23/49861; H01L 23/3107; H01L 23/4952; H01L 23/49562; H01L 21/4825; H01L 21/4842; H01L 21/565; H01L 22/12

(57) ABSTRACT

According to one embodiment, a semiconductor device includes a lead frame including a terminal; an element on a first surface of the lead frame; and a package member covering the lead frame and the semiconductor element. The terminal includes a back-side portion provided on a side of a second surface of the lead frame and exposed from the package member in a first direction perpendicular to the first surface, the second surface being opposite to the first surface, a lateral-side portion provided between the first surface and the back-side portion in the first direction and exposed from the package member in a second direction parallel to the first surface, and a recessed portion provided between the lateral-side portion and the back-side portion in the first direction.

### CROSS-REFERENCE TO RELATED APPLICATIONS

This application is based upon and claims the benefit of priority from prior Japanese Patent Application No. 2022-045393, filed Mar. 22, 2022, the entire contents of which are incorporated herein by reference.

### FIELD

Embodiments described herein relate generally to a semiconductor device and a method for manufacturing a semiconductor device.

### BACKGROUND

Semiconductor devices are mounted on various types of electronic apparatuses.

### BRIEF DESCRIPTION OF THE DRAWINGS

FIG. 1 is a bird's eye view of an apparatus including a semiconductor device in an embodiment.

FIG. 2 is a bird's eye view of a configuration example of the semiconductor device in the embodiment.

FIG. 3 is a bird's eye view of a configuration example of the semiconductor device in the embodiment.

FIG. 4 is a plan view of a configuration example of the semiconductor device in the embodiment.

FIG. 5 is a sectional view of a configuration example of the semiconductor device in the embodiment.

FIG. 6 is a sectional view of a configuration example of the semiconductor device in the embodiment.

FIG. 7 is a plan view illustrating a step of a method for manufacturing the semiconductor device in the embodiment.

FIG. 8 is a plan view illustrating a step of a method for manufacturing the semiconductor device in the embodiment.

FIG. 9 is a sectional view illustrating a step of a method for manufacturing the semiconductor device in the embodiment.

FIG. 10 is a sectional view illustrating a step of a method for manufacturing the semiconductor device in the embodiment.

FIG. 11 is a sectional view illustrating a step of a method for manufacturing the semiconductor device in the embodiment.

FIG. 12 is a sectional view illustrating a step of a method for manufacturing the semiconductor device in the embodiment.

FIG. 13 is a sectional view illustrating a step of a method for manufacturing the semiconductor device in the embodiment.

FIG. 14 is a sectional view illustrating a step of a method for manufacturing the semiconductor device in the embodiment.

FIG. 15 is a sectional view illustrating a step of a method for manufacturing the semiconductor device in the embodiment.

FIG. 16 is a sectional view illustrating modifications of the semiconductor device in the present embodiment.

FIG. 17 is a sectional view illustrating a comparative example of the semiconductor device in the present embodiment.

### DETAILED DESCRIPTION

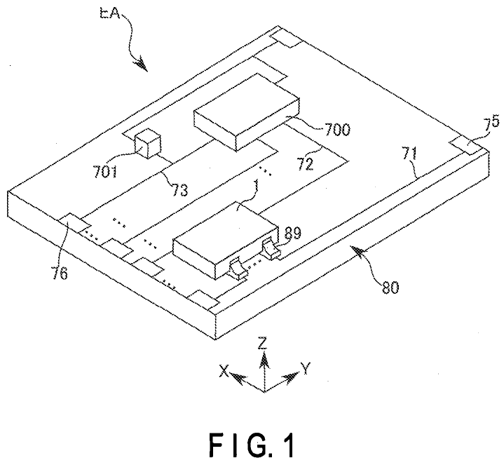

With reference to FIG. 1 to FIG. 17, a semiconductor device and a method for manufacturing the semiconductor device in an embodiment will be described.

The present embodiment will be described below in detail with reference to the drawings. In the following description, constituent elements having the same function and configuration will be given the same reference character.

Further, in the following embodiments, when constituent components (e.g., circuits, interconnects, various types of voltages and signals) with reference numerals to which numerals/alphabetic characters for distinction are appended need not be distinguished from one another, notations (reference numerals) from which the appended numerals/alphabetic characters are omitted will be used.

In general, according to one embodiment, a semiconductor device includes: a lead frame including a first terminal; a semiconductor element provided on a first surface of the lead frame; and a package member with which the lead frame and the semiconductor element are covered. The first terminal includes a back-side portion that is provided on a side of a second surface of the lead frame and is exposed from the package member in a first direction perpendicular to the first surface, the second surface being opposite to the first surface, a lateral-side portion that is provided between the first surface and the back-side portion in the first direction and is exposed from the package member in a second direction parallel to the first surface, and a recessed portion that is provided between the lateral-side portion and the back-side portion in the first direction.

### EMBODIMENT

### (1) Configuration Example

FIG. 1 is a diagram used for explaining an apparatus including a semiconductor device 1 in the present embodiment.

As illustrated in FIG. 1, the semiconductor device 1 in the present embodiment is provided in an electrical apparatus EA. For example, the electrical apparatus EA is industrial equipment, a power converter, an onboard device, a home appliance, an acoustic apparatus, a video system, a communication apparatus, a computer system, or the like.

The semiconductor device 1 is disposed on a front surface (hereinafter, also referred to as a mounting surface) of a module substrate (also referred to as a motherboard or a printed-circuit board) 80 together with one or more other devices (e.g., another semiconductor device or an electronic component) 700 and 701.

The module substrate 80 includes a plurality of interconnects 71, 72, and 73 and a plurality of terminals 75 and 76.

The interconnects 71, 72, and 73 are provided on the front surface of the module substrate 80 or inside the module substrate 80. The interconnects 71, 72, and 73 are each connected to corresponding one or more of the terminals (connectors, sockets, or slots) 75 and 76 or connected to the devices 1, 700, and 701 on the module substrate 80. To each of the terminals 75 and 76, corresponding one of various types of voltages (e.g., power-supply voltage or a ground voltage) and various types of signals is supplied.

The semiconductor device 1 is connected to the interconnects 71 and 72 of the module substrate 80. For example, on the module substrate 80, the semiconductor device 1 is connected to the terminal 75 via the interconnect 71 and connected to the semiconductor device 700 (or the electronic component 701) via the interconnect 72.

Examples of the semiconductor device 700 includes a semiconductor integrated circuit or a discrete device. Note that the semiconductor device 700 may be a device into which a plurality of semiconductor chips and a plurality of passive elements are modularized. The electronic component 701 is a passive element such as a capacitor, an inductor, a resistor, and a switch.

The semiconductor device 700 and the electronic component 701 are connected to the terminal 76 via the interconnect 73 or are connected to each other via another interconnect.

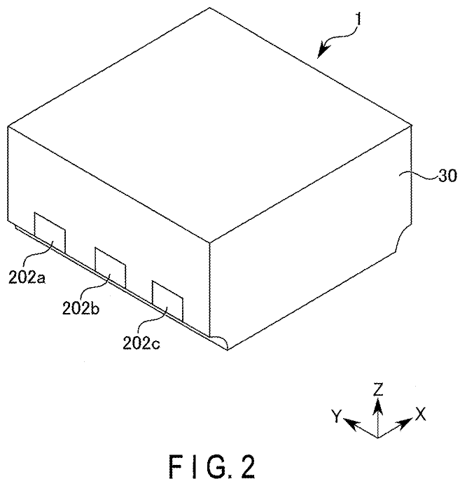

With reference to FIG. 2 to FIG. 6, a configuration example of the semiconductor device in the present embodiment will be described.

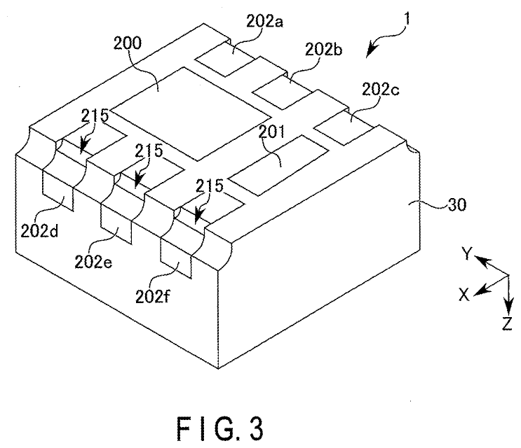

FIG. 2 and FIG. 3 are each a bird's eye view of the configuration example of the semiconductor device 1 in the present embodiment. FIG. 2 illustrates the configuration example of the semiconductor device 1 in the present embodiment as viewed from a front side of the semiconductor device 1. FIG. 3 illustrates the configuration example of the semiconductor device 1 in the present embodiment as viewed from a back side of the semiconductor device 1.

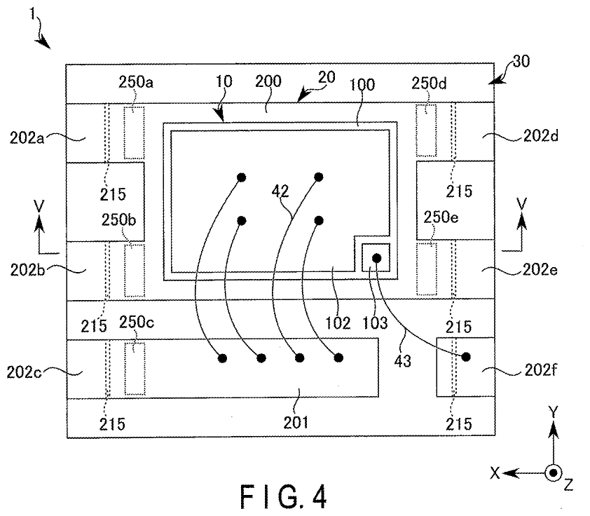

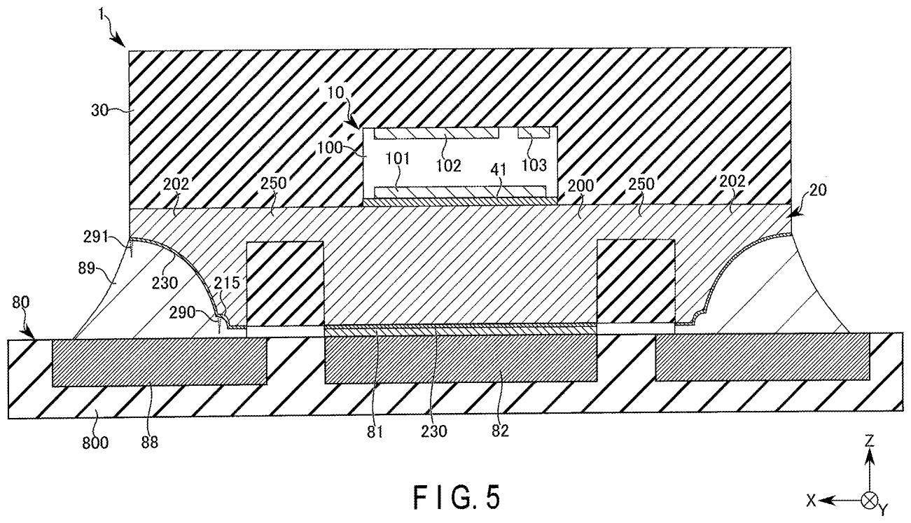

FIG. 4 is a plan view of the configuration example of the semiconductor device 1 in the present embodiment. FIG. 5 is a sectional view illustrating the configuration example of the semiconductor device 1 in the present embodiment. FIG. 5 illustrates a cross section along the line V-V of FIG. 4.

Hereinafter, in the semiconductor device 1 in the present embodiment, a back surface of each constituent member is a surface of the constituent member on the module substrate 80 side, on which the semiconductor device 1 is mounted. A front surface of each constituent member is a surface opposite to the back surface of the constituent member in a direction perpendicular to the back surface.

As illustrated in FIG. 2 to FIG. 5, the semiconductor device 1 in the present embodiment includes a semiconductor element 10, a lead frame 20, and a package member 30.

In the package member 30, the semiconductor element 10 is provided on the lead frame 20.

In a case where the semiconductor device 1 in the present embodiment is a discrete device, the semiconductor element 10 is a field-effect transistor (e.g., MOS transistor), a bipolar transistor, an insulated gate bipolar transistor (IGBT), or a diode. As a more specific example, the semiconductor element 10 is a small-signal transistor. However, the semiconductor element 10 may be a power transistor such as a high-breakdown-voltage transistor (can be also called a high-voltage transistor).

The semiconductor element 10 is, for example, a semiconductor chip (bare chip).

The semiconductor element 10 includes an element unit 100 and a plurality of pads (also referred to as nodes or terminals) 101, 102, and 103.

The pad 101 is provided on a back side of the element unit 100.

In a case where the semiconductor element 10 is a field-effect transistor, the pad 101 is connected to a drain of the transistor. Hereinafter, the pad 101 will be referred to as a drain pad 101.

The pads 102 and 103 are provided on a front side of the element unit 100.

In the case where the semiconductor element 10 is the field-effect transistor, the pad 102 is connected to a source of the transistor. Hereinafter, the pad 102 will be referred to as a source pad 102. In the case where the semiconductor element 10 is the field-effect transistor, the pad 103 is connected to a gate of the transistor. Hereinafter, the pad 103 will be referred to as a gate pad 103.

The drain pad 101 is electrically connected to the lead frame 20 with a conductive member 41 such as conductive paste. The source pad 102 and the gate pad 103 are electrically connected to the lead frame 20 via bonding wires 42 and 43, respectively.

Note that, depending on an internal configuration of the element unit 100, the pad 101 may be used as the source pad, and the pad 102 may be used as the drain pad.

For example, the element unit 100 includes a semiconductor layer of silicon, silicon carbide, silicon-germanium, gallium nitride, gallium arsenide, or the like.

The pads 101, 102, and 103 each include a metal layer of aluminum, copper, or the like.

The package member (also referred to as a sealing member, a molding resin, or a packaging resin) 30 is provided on the semiconductor element 10 and the lead frame 20. On the lead frame 20, the semiconductor element 10 is covered with the package member 30. The package member 30 includes an insulator such as an insulating organic substance (e.g., polyimide). The package member 30 is provided on a front surface of the lead frame 20 and a back surface of the lead frame 20.

The lead frame 20 includes a plurality of terminals 200, 201, and 202 (202a, 202b, 202c, 202d, 202e, and 202f) and a plurality of coupling parts 250 (250a, 250b, 250c, 250d, and 250e). The lead frame 20 includes copper.

The terminals 200, 201, and 202 each include a portion that is exposed from the package member 30.

The terminals 200 and 201 are exposed from the package member 30 on a back surface of the semiconductor device 1. A back surface portion of each of the terminals 200 and 201 functions as an external connecting part. The terminal 200 is adjacent to the terminal 201 in a Y direction.

For example, the terminal 200 is used as an external connection terminal and, at the same time, functions as a die pad (also referred to as a mounting part). The semiconductor element 10 is provided on a front surface of the terminal 200.

The terminal 200 is electrically connected to the drain pad 101 on a back side of the semiconductor element 10 via the conductive member 41 such as conductive paste.

The terminal 200 is electrically connected to a connecting part (interconnect or terminal) 82 of the module substrate 80 via a conductive member 81 such as solder and conductive paste. The connecting part 82 is provided on a substrate member 800 of the module substrate 80 (or inside the substrate member 800).

The terminal 201 is electrically connected to the source pad 102 provided on a front surface of the semiconductor element 10 via the bonding wires 42.

The terminals 202a, 202b, and 202c are provided on one end side of the semiconductor device 1 in an X direction. The terminals 202a and 202b are adjacent to the terminal 200 on the one end side of the semiconductor device 1 in the X direction.

For example, the terminals 202a and 202b are connected to the terminal 200 via the coupling parts 250a and 250b, respectively.

The terminal 202c is adjacent to the terminal 201 on the one end side of the semiconductor device 1 in the X direction. The terminal 202c is electrically connected to the terminal 201 via the coupling part 250c. The terminal 202c is electrically isolated from the terminals 200, 202a, 202b, 202d, 202e, and 202f.

The terminals 202d, 202e, and 202f are provided on another end side of the semiconductor device 1 in the X direction. The terminals 202d and 202e are adjacent to the terminal 200 on the other end side of the semiconductor device 1 in the X direction.

For example, the terminals 202d and 202e are connected to the terminal 200 via the coupling parts 250d and 250e, respectively.

The terminal 202f is adjacent to the terminal 201 on the other end side of the semiconductor device 1 in the X direction. The terminal 202f is isolated from the terminals 200, 201, 202a, 202b, 202c, 202d, and 202e.

The terminals 202a 202b, 202d, and 202e is electrically connected to the drain pad 101, which is provided on the back side of the semiconductor element 10, via the coupling parts 250, the terminal 200, and the conductive member 41. The terminal 202c is electrically connected to the source pad 102, which is provided on a front side of the semiconductor element 10, via the coupling part 250c, the terminal 201, and the bonding wires 42. The terminal 202f is electrically connected to the gate pad 103, which is provided on the front side of the semiconductor element 10, via the bonding wire 43.

For example, a portion of each of the terminals 200, 201, and 202 that is exposed from the package member 30 includes a plating layer 230.

Note that the coupling parts 250 is covered with the package member 30 without being exposed from the package member 30.

The lead frame 20 (the terminals 200, 201, and 202 and the coupling parts 250) includes a metal such as copper and aluminum. The plating layer 230 includes copper.

As illustrated in FIG. 2 to FIG. 5, in the semiconductor device 1 in the present embodiment, the terminals 202 each have a wettable flank (WF) structure. In the present embodiment, the terminals 202 are each provided with a recessed portion (also referred to as stepped portion) 215.

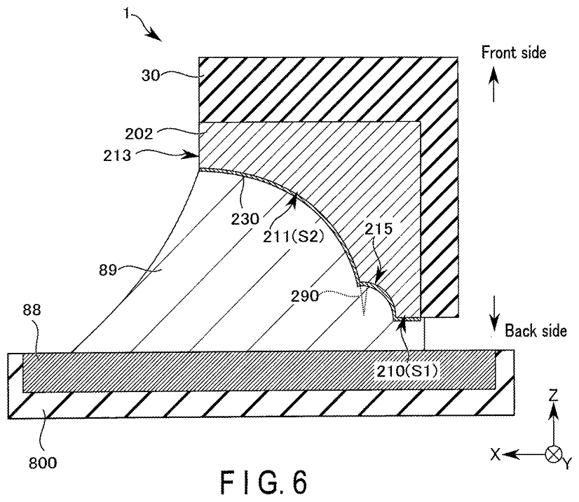

FIG. 6 is a sectional view illustrating a configuration example of a terminal 202 having the WF structure in the semiconductor device 1 in the present embodiment.

As illustrated in FIG. 6, the terminal 202 is exposed on the back side of the semiconductor device 1 and is exposed on a lateral side of the semiconductor device 1.

The terminal 202 further includes a back-side portion 210 and a lateral-side portion (also referred to as a bent portion or a half-cut portion) 211.

The back-side portion 210 of the terminal 202 includes a back surface S1 that is flat. For example, the back surface S1 is substantially parallel to the front surface of the semiconductor device 1. The back-side portion 210 is exposed from the package member 30 in a Z direction.

The lateral-side portion 211 of the terminal 202 includes a lateral surface S2 that is curved. For example, the lateral-side portion 211 includes a quarter-round (or quarter-ellipse) curved surface (lateral surface S2) when viewed from the Y direction. The lateral-side portion 211 is exposed from the package member 30 in the X direction.

The terminal 202 is electrically connected to a connecting part (interconnect or terminal) 88 of the module substrate 80 with a conductive member 89 such as solder. For example, with the solder 89, the back-side portion 210 and the lateral-side portion 211 of the terminal 202 are covered, via the plating layer 230. The connecting part 88 is provided on the substrate member 800 of the module substrate 80 (or inside the substrate member 800).

Of a plurality of portions constituting the terminal 202, a portion that is located closer to the front side of the semiconductor device 1 than the lateral-side portion 211 in the Z direction and has a flat surface on the lateral side of the semiconductor device 1 is referred to as an upper portion 213. Note that an exposed surface of the upper portion 213 (lateral surface) is to be exposed after the plating layer 230 is formed. The plating layer 230 is therefore not provided on the exposed surface of the upper portion 213. On the exposed surface of the upper portion 213, an oxidized layer (not illustrated) can be formed. For example, the solder 89 is not provided on the exposed surface of the upper portion 213.

The terminal 202 includes a recessed portion 215 at the back-side portion 210 (and the lateral-side portion 211) of the terminals 202.

The recessed portion 215 is provided within a boundary area between the back-side portion 210 and the lateral-side portion 211.

At a portion at which the recessed portion 215 is provided, the terminal 202 is recessed from the back side of the semiconductor device 1 toward the front side of the semiconductor device 1. The recessed portion 215 includes a quarter-round (or quarter-ellipse) curved surface when viewed from the Y direction.

The recessed portion 215 is provided upward in the Z direction of (closer to the front side of the semiconductor device 1 than) the back-side portion 210.

An edge portion of the recessed portion 215 on the front side of the semiconductor device 1 in the Z direction is located upward in the Z direction of (closer to the front side of the semiconductor device 1 than) the back-side portion 210 of the terminal 202. Hereinafter, the edge portion of the recessed portion 215 located on the front side of the semiconductor device 1 in the Z direction will be referred to as an upper edge, and an edge portion of the recessed portion 215 located on the back side of the semiconductor device 1 in the Z direction will be referred to as a lower edge.

The upper edge of the recessed portion 215 is connected to one end (a lower edge) of the lateral-side portion 211. The lower edge of the recessed portion 215 is connected to one end of the back-side portion 210.

A dimension of the recessed portion 215 in the Z direction is smaller than a dimension of the lateral-side portion 211 in the Z direction.

For example, when the lead frame 20 is subjected to dicing, a burr 290 may be formed at a boundary portion between the recessed portion 215 and the lateral-side portion 211 (at the upper edge of the recessed portion 215). The burr 290 extends in the Z direction. The burr 290 protrudes from the recessed portion 215 toward the module substrate 80. For example, the burr 290 is covered with the plating layer 230.

In the present embodiment, the burr 290 formed appears on the upper edge side of the recessed portion 215 (an opposite side to the back surface). A portion of the burr 290 at the recessed portion 215 is located closer to the front side of the semiconductor device 1 than the back-side portion 210.

Therefore, consider a case where a burr is formed on the back-side portion 210; compared with a length of the burr protruding from the back surface S1, a length of the burr 290 protruding from the back surface S1 of the terminal 202 is small.

Note that, as illustrated in FIG. 5, a burr 291 may be formed at a boundary portion between the lateral-side portion 211 and the upper portion 213 through a step of dicing the semiconductor device 1.

### (2) Manufacturing Method

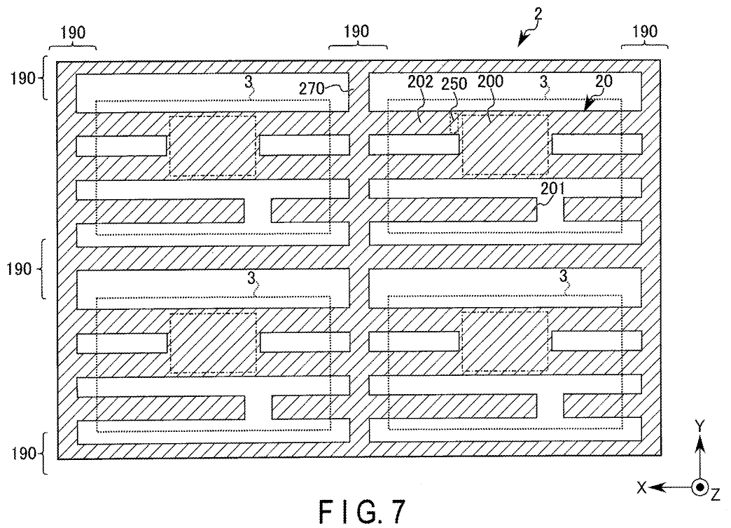

With reference to FIG. 7 to FIG. 15, a method for manufacturing the semiconductor device 1 in the present embodiment (and a method for manufacturing an apparatus including the semiconductor device 1 in the present embodiment) will be described.

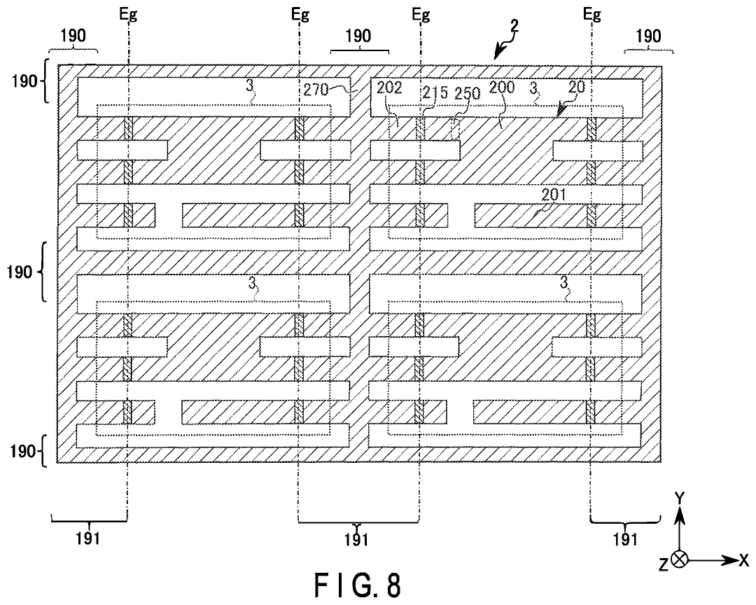

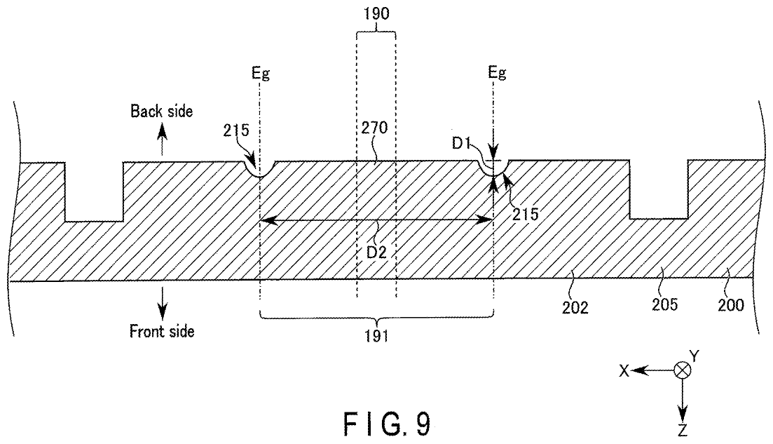

FIG. 7 and FIG. 8 are plan views each illustrating a step of the method for manufacturing the semiconductor device 1 in the present embodiment. FIG. 9 to FIG. 15 are sectional views each illustrating a step of the method for manufacturing the semiconductor device 1 in the present embodiment. FIG. 7 to FIG. 15 each illustrate, in a clipping manner, given portions of constituent members used for describing the method for manufacturing the semiconductor device 1.

As illustrated in FIG. 7, a metal plate 2 including a plurality of lead frames 20 is formed. The metal plate 2 includes, for example, copper (or aluminum). Note that FIG. 7 illustrates structures of the lead frames 20 as viewed from their front side.

The lead frames 20 are connected to one another with connecting portions (marginal portions) 270 in the metal plate 2.

Dicing areas (also referred to as full-cut areas) 190 surround device areas 3 each of which is to be a constituent part of the semiconductor device 1. The lead frame 20 is formed within the device area 3.

A dimension of the dicing area 190 in its width direction is equivalent to a width of a dicing blade (a thickness of a blade of the dicing blade) that is used in a step of full-cutting the metal plate 2 described later.

Through a step described later, the connecting portions 270 of the metal plate 2 are divided along the dicing areas 190, by which the lead frames 20 independent from one another are formed.

FIG. 8 illustrates structures of the lead frames 20 as viewed from their back side.

As illustrated in FIG. 8 and FIG. 9, on the back side of the metal plate 2, recessed portions 215 are formed on edge portions Eg in a width direction (the X direction) of half-cutting areas 191 in a step of half-cutting described later. The half-cutting areas 191 extend in the Y direction. The edge portions (hereinafter, also referred to as half-cutting edges) Eg of the half-cutting areas 191 are present on terminals 202 of the lead frames 20. The recessed portions 215 each include a quarter-round (or quarter-ellipse) shape when viewed from the Y direction.

For example, formation of the recessed portions 215 is performed before mounting semiconductor elements 10 on the lead frames 20.

The recessed portions 215 are formed by etching the metal plate 2 or pressing the metal plate 2 with a press machine.

Portions of the metal plate 2 where the recessed portions 215 are formed are recessed with respect to the other portions of the metal plate 2. A dimension (depth) D1 of the recessed portions 215 in the Z direction is about several tens of μm to several hundred μm. For example, the depth D1 of the recessed portions 215 is about 30 μm to 100 μm.

A distance D2 between bottom portions of two adjacent recessed portions 215 (upper edges of the recessed portions 215 described above) in the width direction of each half-cutting area 191 is desirably, substantially equal to a width of the dicing blade used in a step of half-cutting described later.

Note that the distance D2 between the bottom portions of the two recessed portions 215 need not match the width of the dicing blade as long as the recessed portions 215 are formed at locations that overlap with corresponding edge portions in the width direction of the dicing blade for the step of half-cutting.

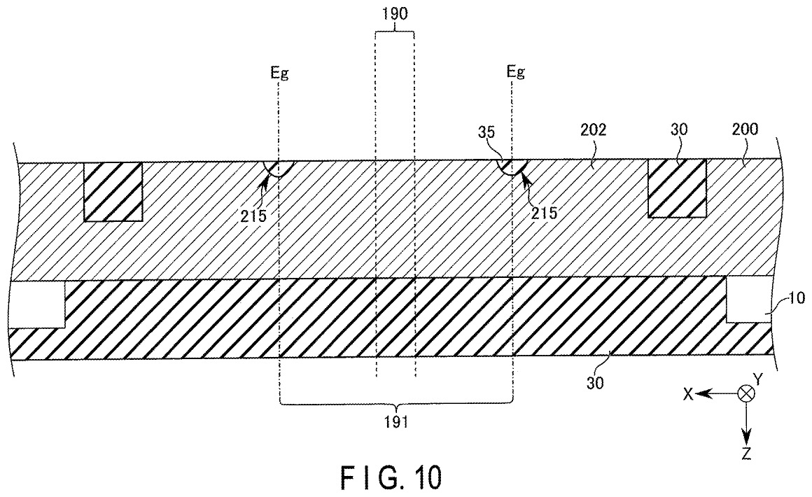

As illustrated in FIG. 10, semiconductor elements 10 are each mounted on a front surface of a lead frame 20 of the metal plate 2. The semiconductor element 10 are each placed on a terminal (mounting part) 200 of the lead frame 20. A pad 101 of the semiconductor element 10 is electrically connected to the mounting part 200 via a conductive member 41. A plurality of pads 102 and 103 of the semiconductor element 10 are electrically connected to terminals 201 and 202 of the lead frames 20, respectively, via bonding wires (not illustrated) by wire bonding.

After the semiconductor elements 10 are electrically connected to the lead frames 20, the semiconductor elements 10 are sealed with package members 30. The package members 30 are thereby formed on the semiconductor elements 10 and the lead frames 20. On the back side of the lead frames 20, back surfaces of terminals 201, 202, and 203 are exposed. Note that exposed surfaces of package members 30 may be retreated through etching.

When the semiconductor elements 10 are being sealed, package members 35 are embedded in the recessed portions 215. Note that the package members 35 need not be embedded in the recessed portions 215.

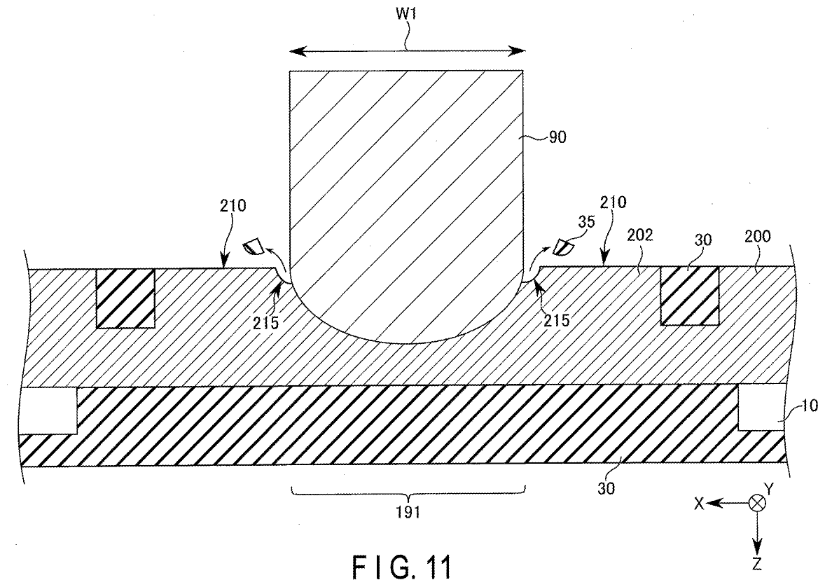

As illustrated in FIG. 11, the step of half-cutting the metal plate 2 is performed with a dicing blade 90 having a first blade width W1. Portions of the metal plate 2 in the half-cutting areas 191 are thereby removed.

The dicing blade 90 comes into contact with recessed portions 215. Edges of the dicing blade 90 in its width direction overlap with certain portions of recessed portions 215. Portions of the recessed portions 215 are thereby ground.

In the present embodiment, the back-side portion 210 does not come into contact with the dicing blade 90.

The package members 35 in the recessed portions 215 are removed through the step of half-cutting by contacts between the package member 35 and the dicing blade 90 or impacts of the dicing.

If some package members 35 are not removed through the step of half-cutting, the package members 35 may be removed from the recessed portions 215 through an electric deflashing (ED) process or a water jet cleaning process to be performed after the step of half-cutting.

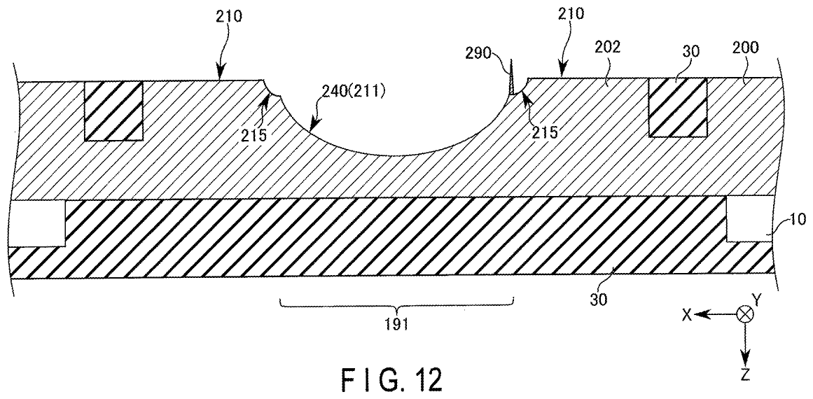

As illustrated in FIG. 12, through the step of half-cutting illustrated in FIG. 11, a trench 240 is formed in the metal plate 2. This forms a curved lateral-side portion 211 at a terminal 202 having the WF structure.

By grinding the metal plate 2 with the dicing blade 90, a burr 290 may be formed in an area in a vicinity of a boundary between a recessed portion 215 and the trench 240.

The burr 290 is formed in a recess of the recessed portion 215 at a portion at which the recessed portion 215 and the dicing blade 90 are brought into contact with each other.

As described above, since the back-side portion 210 does not come into contact with the dicing blade 90, no burr appears on the back-side portion 210.

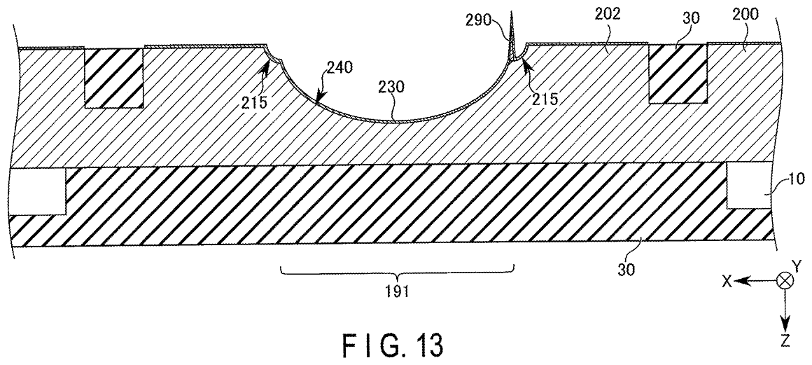

As illustrated in FIG. 13, after the step of half-cutting, a plating process is performed on the metal plate 2. This forms a plating layer 230 on the lead frames 20. Terminal 202 are covered with the plating layer 230.

For example, a member (material) of the burr 290 is the same as a member of the terminals 202. The plating layer 230 is therefore also formed on the burr 290. This increases a size of the burr 290. Note that a plating layer 230 thicker than a plating layer 230 on a terminal 202 may be formed on the burr 290 depending on a shape of the burr 290.

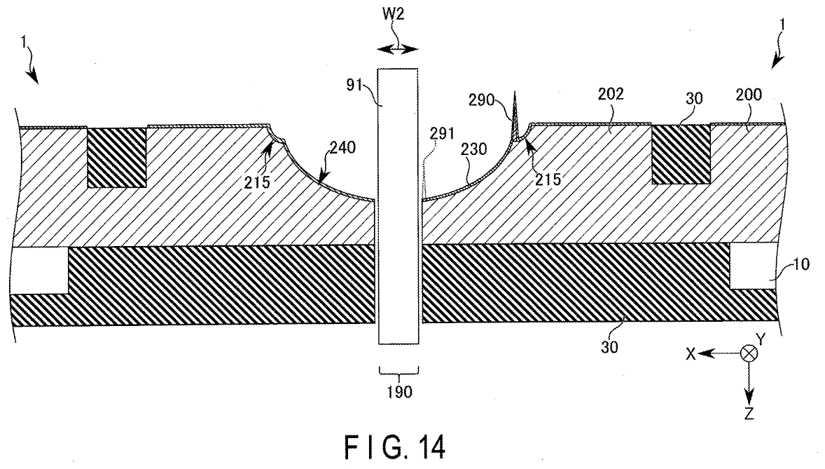

As illustrated in FIG. 14, the step of full-cutting is performed on the metal plate 2 with a dicing blade 91 having a second blade width W2. The second blade width W2 is smaller than the first blade width W1.

The metal plate 2 is ground along the dicing areas 190. The connecting portions 270 in the dicing areas 190 are removed from the metal plate 2 by dicing in the step of full-cutting. A metal plate 2 is divided for each device area 3. This causes a plurality of semiconductor devices 1 to be separated from one another.

As a result, the semiconductor devices 1 each including terminals 202 each having the WF structure are formed.

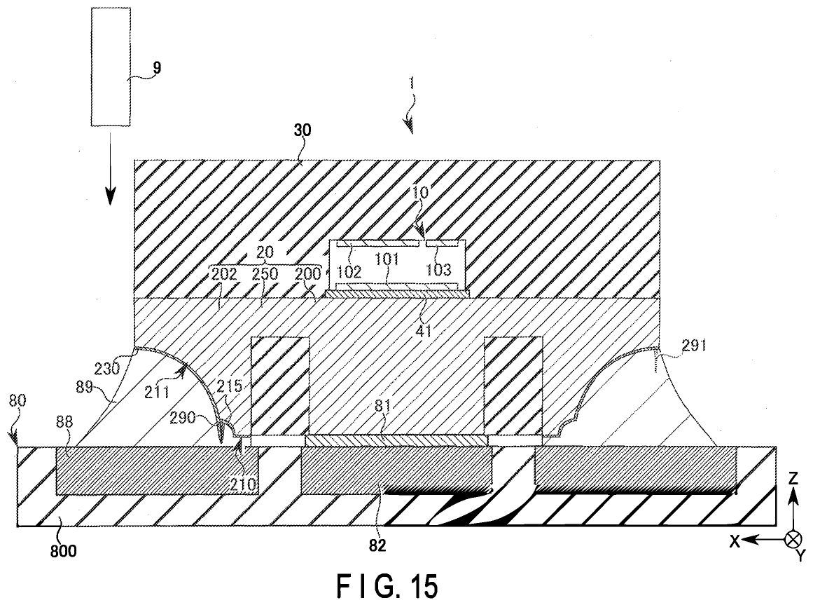

As illustrated in FIG. 15, the semiconductor device 1 in the present embodiment is subjected to various processes and then mounted on a module substrate 80. For example, a terminal 202 of the semiconductor device 1 having the WF structure is connected to a connecting part (interconnect or terminal) 88 of the module substrate 80 with solder 89.

The terminal 202 having the WF structure allows a fillet (side fillet) of the solder 89 to be formed on a lateral-side portion 211 of the terminal 202.

Thereafter, various inspections including an automated optical inspection (AOI) are performed on the semiconductor device 1 on the module substrate 80 with a test apparatus 9.

For example, by the AOI, a shape of the side fillet of the solder 89 formed on the terminal 202 is inspected. This determines a quality of a bonding condition between the semiconductor device 1 and the module substrate 80.

After various inspections, the module substrate 80 on which the semiconductor device 1 in the present embodiment is mounted or an apparatus EA including the semiconductor device 1 in the present embodiment is shipped to a market or a user.

### (3) Modifications

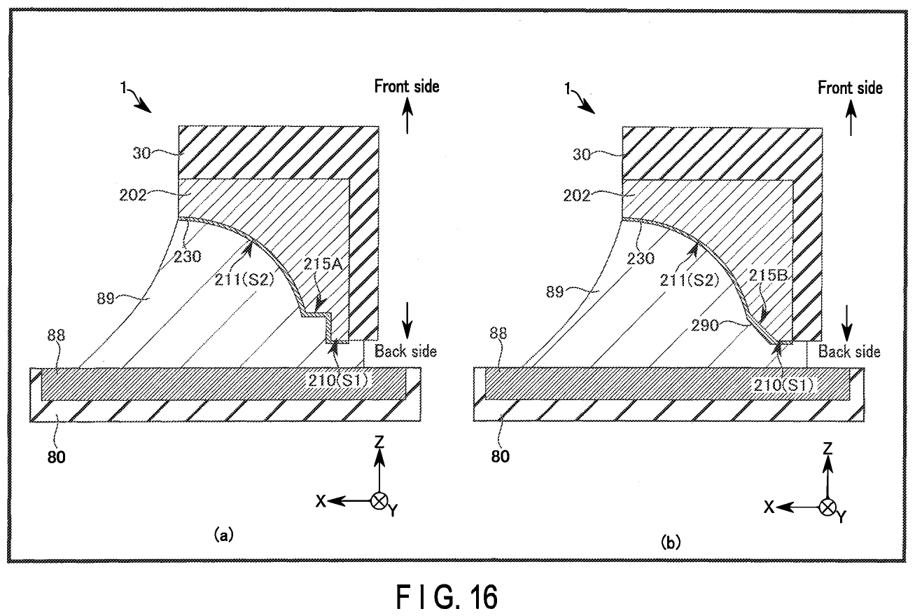

FIG. 16 is a sectional view illustrating modifications of the semiconductor device 1 in the present embodiment.

The structure of a recessed portion 215 provided between a back-side portion 210 and a lateral-side portion 211 of a terminal 202 is not limited to the example described above.

As illustrated in (a) in FIG. 16, a recessed portion 215A may have a structure in which a flat surface parallel to a front surface of a semiconductor device 1 is connected to a flat surface perpendicular to the front surface of the semiconductor device 1. In this case, rectangular recesses are formed in a metal plate 2 in a step of forming the recessed portions 215 illustrated in FIG. 9.

Alternatively, as illustrated in (b) in FIG. 16, a recessed portion 215B may have a structure that is formed of a flat surface inclined with respect to a front surface of a semiconductor device 1 between a back-side portion 210 and a lateral-side portion 211. In this case, triangular recesses are formed in a metal plate 2 in a step of forming the recessed portions 215 illustrated in FIG. 9.

In each of (a) and (b) in FIG. 16, a burr 290 that appears in the step of half-cutting is formed at a boundary portion between the recessed portion 215A or 215B and the lateral-side portion 211. As seen from the above, when steps 215A and 215B are formed between the back-side portion 210 and the lateral-side portion 211, substantially the same effect as in the example described above can be provided by the structures of FIG. 16.

### (4) Conclusion

In a process for manufacturing a semiconductor device, a burr may appear at a contact portion between an edge portion of a dicing blade and a lead frame through a step of grinding the lead frame with the dicing blade.

Due to the burr protruding a back surface of the semiconductor device, a gap between the back surface of the semiconductor device and a module substrate is increased. This can cause a height of the semiconductor device to fail to satisfy standards and specifications. Further, the burr appearing can be peeled off from a terminal after the shipment of the semiconductor device, manufacturing a scrap in a product.

In a semiconductor device having the WF structure, the burr appearing can make it difficult to form a favorable side fillet of solder. This can deteriorate a mountability of the semiconductor device with respect to the module substrate or makes it difficult to perform a mounting inspection on the semiconductor device.

In the semiconductor device 1 in the present embodiment including the terminals 202 each having the WF structure, the recessed portion 215 is provided between the back-side portion 210 and the lateral-side portion 211 of the terminal 202.

In the step of half-cutting for forming the lateral-side portion 211 of the WF structure, the recessed portion 215 comes into contact with a dicing blade.

For that reason, in the present embodiment, the burr 290 that appears in the step of half-cutting is formed in the recessed portion 215, which is located closer to the front side of the semiconductor device 1 than the back-side portion 210 of the semiconductor device 1. As a result, with respect to the back-side portion 210 of the semiconductor device 1, a length of burr 290 at the recessed portion 215 by which the burr 290 protrudes from the back surface of the semiconductor device 1 is small as compared with a case where the burr 290 is formed on the back surface of the semiconductor device 1.

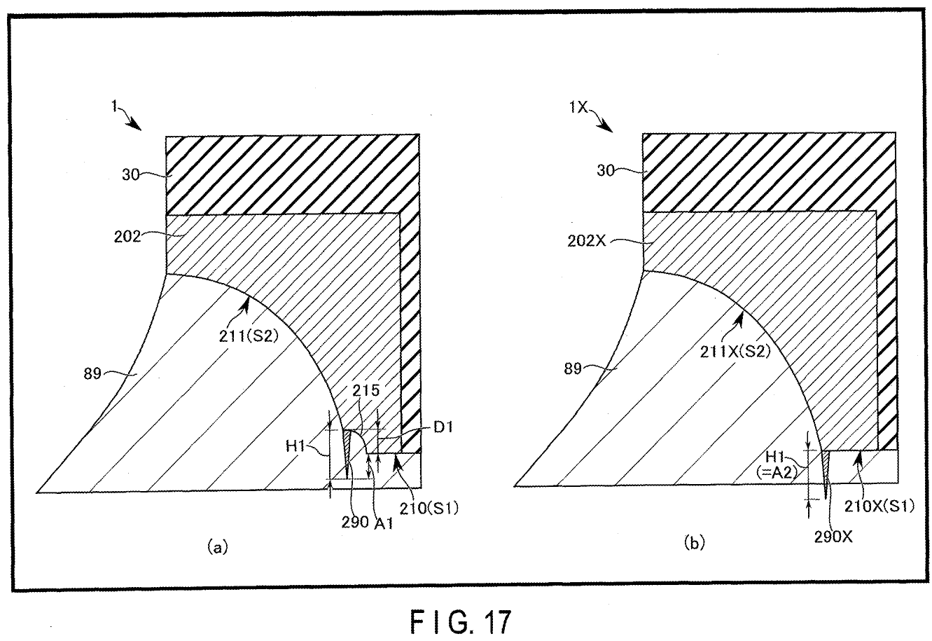

FIG. 17 is a diagram used for describing an advantageous effect of the semiconductor device 1 in the present embodiment. Note that the plating layer 230 is not illustrated in FIG. 17 for a better viewability.

In FIG. 17, (a) illustrates a structure of a terminal 202 of the semiconductor device 1 in the present embodiment. In FIG. 17, (b) illustrates a structure of a terminal 202x of the semiconductor device 1X in a comparative example.

As illustrated in (a) in FIG. 17, the burr 290 appears in the recessed portion 215 at a boundary portion between the recessed portion 215 and the lateral-side portion 211. The recessed portion 215 has a depth D1 in the Z direction. The burr 290 has a dimension H1 in the Z direction.

In this case, a length A1 by which the burr 290 protrudes from the back-side portion 210 is “H1-D1.”

As illustrated in (b) in FIG. 17, in a terminal portion 202X of the semiconductor device 1X in the comparative example, which includes no recessed portion 215, a lateral-side portion 211X is continued from a back-side portion 210X.

In the step of half-cutting, the dicing blade comes into contact with the back-side portion 210X.

Therefore, in the comparative example, a burr 290X is formed at an edge portion of the back-side portion 210X at a boundary portion between the back-side portion 210X and the lateral-side portion 211X. The burr 290X has the dimension H1 in the Z direction. In this case, a length A2 by which the burr 290X protrudes from the back-side portion 210X is “H1.”

As seen from the above, even when the dimension H1 of the burr 290 in the Z direction is the same as the dimension H1 of the burr 290X in the Z direction, the protruding length A1 of the burr 290 with respect to the back surface of the semiconductor device 1 in the present embodiment is smaller than the protruding length A2 of the burr 290X with respect to a back surface of the semiconductor device 1X in the comparative example by a length of a portion of the burr 290 formed within the recessed portion 215. As a result, in the present embodiment, an adverse effect of the burr 290 in mounting the semiconductor device 1 with respect to the module substrate 80 is mitigated.

A flatness of the back surface of the semiconductor device 1 in the present embodiment is therefore improved. As a result, a favorable bonding is formed between the semiconductor device 1 in the present embodiment and the module substrate 80.

Consequently, a mounting quality of the semiconductor device 1 in the present embodiment with respect to the module substrate 80 is improved.

Further, as a result of the improvement in the flatness of the back surface of the semiconductor device 1 (reduction in the protruding length of the burr), a gap between the back surface of the semiconductor device 1 and the module substrate 80 becomes small.

In the semiconductor device 1 including the terminal 202 having the WF structure, this increases a wicking-up amount of the solder 89 with respect to the terminal 202 having the WF structure.

Thus, side fillets of the solder 89 is likely to be formed on the terminals 202 each having the WF structure.

As a result, the inspection of a mounting condition of the semiconductor device 1 by the AOI is facilitated. The semiconductor device 1 in the present embodiment can therefore improve a precision of the inspection.

Consequently, a reliability of a quality of the apparatus including the semiconductor device 1 in the present embodiment is improved.

As described above, the semiconductor device in the present embodiment can improve a reliability of its mounting.

### (5) Other Respects

The semiconductor device 1 in the present embodiment may be a semiconductor integrated circuit, an image sensor, an optical device, or a memory device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a lead frame including a first terminal;
a semiconductor element provided on a first surface of the lead frame; and
a package member with which the lead frame and the semiconductor element are covered, wherein
the first terminal includes
a back-side portion that is provided on a side of a second surface of the lead frame and is exposed from the package member in a first direction perpendicular to the first surface, the second surface being opposite to the first surface,
a lateral-side portion that is provided between the first surface and the back-side portion in the first direction and is exposed from the package member in a second direction parallel to the first surface, and
a recessed portion that is provided between the lateral-side portion and the back-side portion in the first direction.

2. The semiconductor device according to claim 1, wherein an upper edge of the recessed portion is provided upward of the back-side portion in the first direction.

3. The semiconductor device according to claim 1, wherein the first terminal further includes a protruding portion provided in the recessed portion.

4. The semiconductor device according to claim 1, wherein the first terminal has a wettable flank (WF) structure.

5. The semiconductor device according to claim 1, wherein an upper edge of the recessed portion in the first direction is connected to one edge of the lateral-side portion, and a lower edge of the recessed portion in the first direction is connected to one edge of the back-side portion.

6. The semiconductor device according to claim 1, wherein the recessed portion includes a third surface that is curved.

7. The semiconductor device according to claim 1, wherein
the back-side portion includes a fourth surface that is parallel to the first surface, and
the lateral-side portion includes a fifth surface that is curved.

8. The semiconductor device according to claim 1, further comprising solder with which the lateral-side portion, the back-side portion, and the recessed portion are covered.

9. The semiconductor device according to claim 8, wherein the solder protrudes from the lateral-side portion in the second direction.

10. The semiconductor device according to claim 1, further comprising a plating layer provided on the first terminal.

11. The semiconductor device according to claim 1, wherein
the lead frame includes
a first portion that overlaps with the semiconductor element on the first surface and is exposed on the second surface, and
a second portion that is provided between the first terminal and the first portion.

12. A method for manufacturing a semiconductor device, the method comprising:
forming a plurality of lead frames in a metal plate, the lead frames each including a plurality of terminals;
forming recessed portions in boundary areas between half-cutting areas and each of the terminals in the metal plate;
grinding the terminals such that the recessed portions overlap with edges of a first blade having a first width and forming a trench in the half-cutting area of the metal plate; and
grinding the terminals in the trench with a second blade having a second width to divide the lead frames into each other, the second width being smaller than the first width.

13. The method for manufacturing a semiconductor device according to claim 12, the method further comprising:
connecting semiconductor elements to the respective lead frames after the forming of the recessed portions and before the forming of the trenches; and
forming package members on the respective semiconductor elements before the forming of the trenches.

14. The method for manufacturing a semiconductor device according to claim 12, the method further comprising performing a plating process on the terminals after the forming of the trenches.

15. The method for manufacturing a semiconductor device according to claim 12, the method further comprising:
mounting a semiconductor device including the lead frame on a substrate such that the terminals are connected to connecting parts of the substrate via solder; and
inspecting the semiconductor devices on the substrate by an automated optical inspection.

16. The method for manufacturing a semiconductor device according to claim 12, wherein the first terminal has a wettable flank (WF) structure.

17. The method for manufacturing a semiconductor device according to claim 12, wherein
the terminals each include
a back-side portion that is provided on a first surface side of the lead frame, and
a lateral-side portion that is connected to the back-side portion via the recessed portion, wherein
the lateral-side portion faces the trench.

18. The method for manufacturing a semiconductor device according to claim 12, wherein at least one of the terminals further includes a protruding portion that is provided in the recessed portion.
